(19) United States
(12) Patent Application Publication
(10) Pub. No.: US 2004/0026122 A1
(43) Pub. Date: Feb. 12, 2004

(54) Printed circuit board and production method therefor, and laminated printed circuit board

(76) Inventors: Katsuhiko Hayashi, Saitama (JP); Tatsuo Kataoka, Saitama (JP); Hirokazu Kawamura, Saitama (JP); Akira Ichiryu, Saitama (JP)

Correspondence Address: YOUNG & THOMPSON, 745 SOUTH 23RD STREET 2ND FLOOR, ARLINGTON, VA, 22202

(21) Appl. No.: 10/297,804

(22) PCT Filed: Apr. 4, 2002
(86) PCT No.: PCT/JP02/03379

(30) Foreign Application Priority Data
Apr. 6, 2001 (JP) 2001-108381

(51) Int. Cl. H05K 1/03

(52) U.S. Cl. 174/260; 29/830; 29/846; 174/255

(57) ABSTRACT

A printed circuit board comprising an insulating substrate, a via hole (16) formed in the insulating substrate, an implant material (15) filled in the via hole, and wiring patterns formed on the opposite surfaces of the substrates and electrically connected by the implant material, wherein the implant material is selected from a group consisting of acid-free copper, phosphorus-deoxidized copper and tough-pitch copper. Since the via hole comprises high-heat-resisting acid-free copper, phosphorus-deoxidized copper and tough-pitch copper, the printed circuit board is not likely to be deteriorated even when exposed, as is often the case, to a condition that heating/cooling between high temperatures and low temperatures is repeated, and can be used for an extended time while keeping an excellent heat resistance.

### TECHNICAL FIELD

The present invention relates to a printed circuit board and a process for fabricating the same, more particularly to the heat-resistant printed circuit board having a plurality of via-holes which are prepared by filling through-holes with heat-resistant implant material and to the process for fabricating the same.

### BACKGROUND ART

Various circuit boards are used having conductive layers (interconnect patterns) on their top and bottom surfaces. Practical examples thereof include a multi-layered interconnecting board having a rigid substrate made of glass epoxy in addition to a TAB (Tape Automated Bonding) tape, a CSP (Chip Size Package), a BGA (Ball Grid Array), a FPC (Flexible Printed Circuit) having a substrate made of flexible polyimide resin.

The printed circuit board having the interconnect patterns on the top and bottom surfaces is fabricated, for example, in accordance with a conventional method shown in a flowchart of. FIG. 1.

At first, sprocket holes are formed, by punching, through specified positions of a polyimide tape having laminated copper on both of the surfaces. After the top surface of the polyimide tape is smoothened, photoresist applied on the top surface of the film is exposed and developed to form an etching mask. The copper on the film surface is etched by using the etching mask to form interconnect patterns. Similarly, interconnect patterns on the bottom surface of the polyimide tape are formed by the process of the smoothing, the application of the photoresist, the exposure, the development and the etching.

Through-holes are perforated with a punching press machine at specified positions of the polyimide tape having the interconnect patterns formed in the above manner on the top and bottom surfaces. Then, the interconnect patterns on the top and bottom surfaces are electrically connected with each other. The electrical connection is performed by the punching-press of the tin-silver alloy or tin-copper alloy material superposed on the top and bottom surfaces of the polyimide tape to fill the through-holes followed by the caulking with the punching-press machine. The printed circuit board having the ideal electric connection can be obtained by filling the through-holes having diameter of about 100 μm with the tin-silver alloy material.

However, the thermal resistance of the printed circuit board is inferior which is obtained in this manner and the tin-silver alloy or tin-copper alloy material as the implant material is likely to generate defects in the via-holes by the repetition of the heating and cooling. The printed circuit board disadvantageously lacks the connection reliability between the interconnects on the top and bottom surfaces. The melting point of the tin-silver alloy or tin-copper alloy material is relatively low such that a problem may arise that degradation may occur when the material is heated to a temperature beyond the melting point. Although the improvement of the heat resistance is attempted by plating, with gold having underlying nickel, the both ends of the via-holes filled with the above alloy material, the improvement is not necessarily sufficient. The satisfactory results may be obtained depending on the diameters of the through-holes and the kind of the implant material. However, the restriction of the plating material to the gold having the underlying nickel lowers the degree of freedom with respect to products though the use of another plating material is desirous depending on an intended use.

The thickening of the plating thickness of the gold having the underlying nickel is required to sufficiently elevate the heat resistance, thereby increasing the width of the interconnect patterns. Accordingly, the required miniaturization of the interconnects cannot be realized.

### DISCLOSURE OF INVENTION

The present inventors have reached to the present invention that can provide a printed circuit board having excellent heat resistance after investigation of various materials which may be used as an implanting material which fills through-holes. An object of the present invention is to provide the printed circuit board which is usable in a longer period of time and has excellent heat resistance.

The above object can be achieved by providing a print circuit board including a dielectric substrate having via-holes perforated therethrough, an implant material which is filled in the via-holes and selected from a group consisting of oxygen free copper, phosphorus-deoxidized copper and tough pitch copper, and interconnect patterns formed on both surfaces of the substrate and electrically connected to the implant material, or a process of fabricating a print circuit board including the steps of perforating through-holes (basically, in the present invention, an aperture is referred to as a through-hole, and the aperture filled with an implant material is referred to as a via-hole) therethrough, filling the through-holes with an implant material to form via-holes, forming a pair of plated layers on both of top and bottom surfaces of the dielectric substrate including both surface ends of the filled implant materials, and forming interconnect patterns on the plated layers.

In accordance with the print circuit board of the present invention, the print circuit board having the excellent heat resistance can be obtained and used for a longer period of time because the via-holes made of the oxygen free copper, the phosphorus-deoxidized copper, the tough pitch copper or the like reduce the probability of generating deficiencies under the conditions of the repeated heating and cooling between higher temperatures and lower temperatures to which the print circuit board is likely exposed.

The annealing of the oxygen free copper, the phosphorus-deoxidized copper or the tough pitch copper in advance improves the extendibility and the filling ability, thereby providing the print circuit board having the higher performances.

A plated layer may be formed in contact with the implant material filled in the via-holes, thereby further improving the conductivity between the interconnect patterns on the top and bottom surfaces of the print circuit board of the present invention.

The plated layer is desirably a copper plated layer, and the thickness of 1 μm or more thereof effectively prevents the generation of cracks.

A plurality of the print circuit boards may be stacked to provide a layered print circuit board.

In accordance with the process of fabricating the print circuit board, the interconnect patterns having extremely smaller width can be easily formed because the via-holes are formed before the formation of the interconnect patterns or because the interconnect patterns can be freely formed on the conductive plated layer.

Also in this process, the implant material is desirably the highly heat-resistant material such as the oxygen free copper, the phosphorus-deoxidized copper or the tough pitch copper, thereby enabling the free formation of the interconnect patterns and providing the highly heat-resistant print circuit board.

As described above, the present invention is characterized by the use of the oxygen free copper, the phosphorus-deoxidized copper or the tough pitch copper having the excellent heat-resistance singly or the combination thereof, or by the use thereof with a relatively smaller amount of another material.

The oxygen free copper contains oxygen of 0.005% or less for preventing the hydrogen embrittlement. The oxygen free copper is also referred to as OFHC (oxygen free high conductivity copper) and can be prepared in a vacuum melting furnace or an induction furnace having a reductive atmosphere.

The phosphorus-deoxidized copper contains an extremely lower amount of oxygen, which is prepared by deoxidation or by removing the oxygen as oxide such as P₂O₅, thereby remaining a smaller amount of the phosphorous.

The tough pitch copper containing a small amount of oxygen (0.02 to 0.05%) as Cu₂O refers to refined copper, which is prepared by melt-refining electrolytic copper in a reflection furnace to leave the oxygen therein at about 0.02% and then removing, as their oxides, impurities such as As, Sb and P.

These coppers generally contains about 0 to 0.05% of oxygen and a smaller amount of other impurities, have higher heat-resistance than the tin-silver alloy material and the tin-copper alloy material conventionally used for filling the through-holes, and elevating the heat-resistance of the print circuit board at 260° C. which is a reflow temperature for mounting soldering balls. The use of the oxygen free copper, the phosphorus-deoxidized copper or the tough pitch copper annealed in advance further increases the effect.

While the through-holes can be conveniently and most desirably formed by means of punching, a drill or laser may also be used. The use of the laser requires the removal of smear generated with the heat of the laser.

While the implant material can be filled in the through-holes by using any method, the filling is desirably conducted by the punching with a punching-press machine or a punching mold which is the same as that used for the conventional through-hole formation. In addition, a screen printer may be used.

When the through-hole formation and the implant material filling are conducted as a single punching operation, the top end of the formed via-hole is liable to be rounded to decrease the conductivity reliability. Accordingly, after the through-hole formation, the implant material is desirably filled in the through-holes.

A print circuit board having material used in the ordinary print circuit board can be used without restriction as the print circuit board of the present invention, and the use of polyimide resin is desirable. The material of and the method of forming the interconnect patterns are not especially restricted, and the desired interconnect patterns may be prepared by the smoothing of the copper plated layer, the masking by the application of photoresist, the exposure, the development, and the etching.

The number of the through-holes to be formed depends on the number of the interconnect patterns to be electrically connected and their positional relationship, and their diameters are desirably minimum provided that the sufficient electrical connection is secured.

The conductive plated layer, for example, a copper plated layer is desirably coated on the surface of the interconnect patterns made of copper or the like, and the formation of the plated layer further increases the reliability of the electrical connection.

The conductive plated layer is desirably formed before the formation of the interconnect patterns, thereby freely forming the interconnect patterns on the conductive plated layer or enabling the easier formation of the interconnect patterns having the extremely smaller width.

The print circuit board of the present invention has the via-holes filled with the implant material which is selected from a group consisting of the oxygen free copper, the phosphorus-deoxidized copper and the tough pitch copper, ordinarily has a via-hole resistance below 3 mΩ/hole depending on the fabrication conditions, and obtains the extremely excellent conductivity.

In accordance with the process of the present invention in which the conductive plated layer is formed before the interconnect pattern formation, the interconnect patterns can be freely formed on the conductive plated layer and the interconnect patterns having the extremely smaller width can be easily formed.

### BRIEF DESCRIPTION OF DRAWINGS

FIG. 1 is a flowchart showing a conventional process for fabricating a print circuit board having interconnect patterns on its top and bottom surfaces.

FIG. 2 is a vertical sectional view exemplifying a series of process steps for fabricating 2-metal TAB or the print circuit board.

FIG. 3 is a top plan view showing the 2-metal TAB of an embodiment.

FIG. 4 is an enlarged view showing a land section of the 2-metal TAB of FIG. 3.

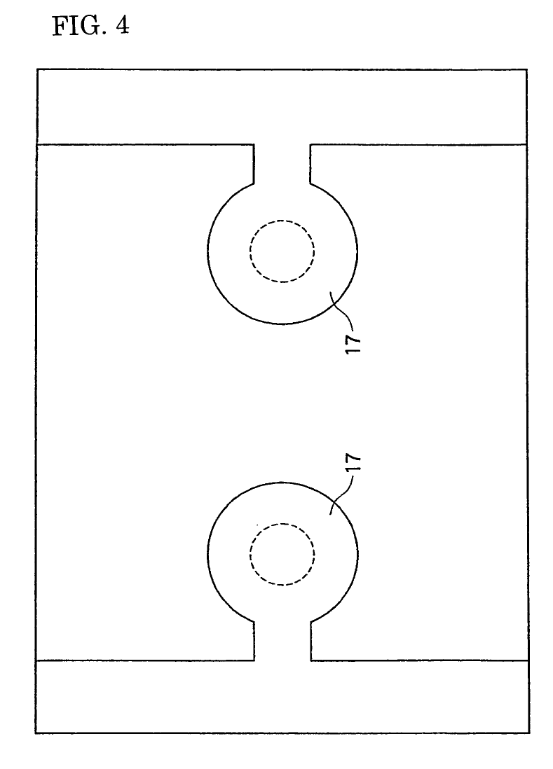

FIG. 5 is a bottom view showing the 2-metal TAB of the embodiment.

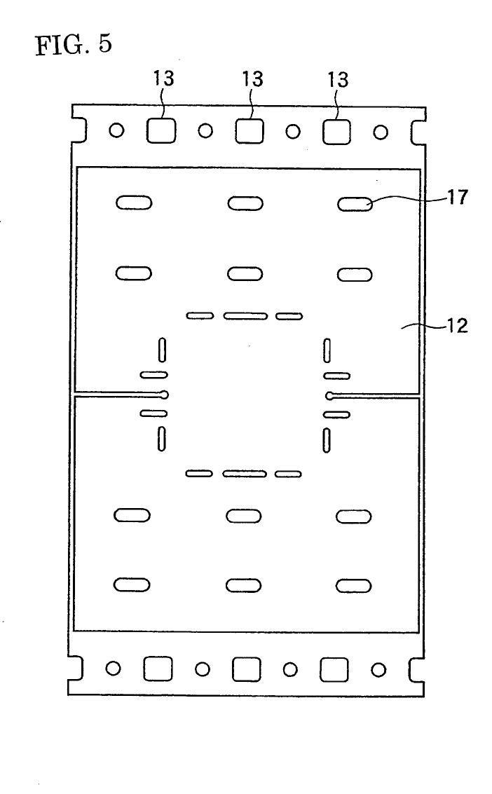

FIG. 6 is an enlarged view showing a land section of the 2-metal TAB of FIG. 5.

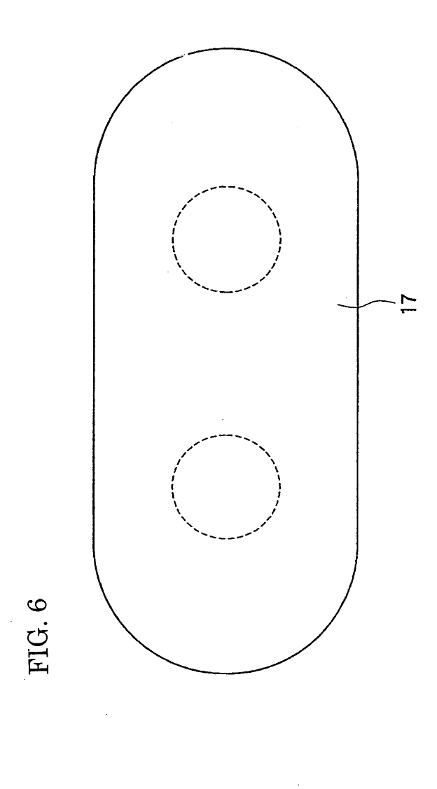

FIG. 7 is a vertical sectional view showing a print circuit board having a relatively thicker copper plated layer.

FIG. 8 is a vertical sectional view showing a print circuit board having a relatively thinner copper plated layer.

### BEST MODE FOR IMPLEMENTING INVENTION

Although an embodiment of a process of fabricating a print circuit board in accordance with the present invention will be described referring to the annexed drawings, the present invention shall not be deemed to be restricted thereto.

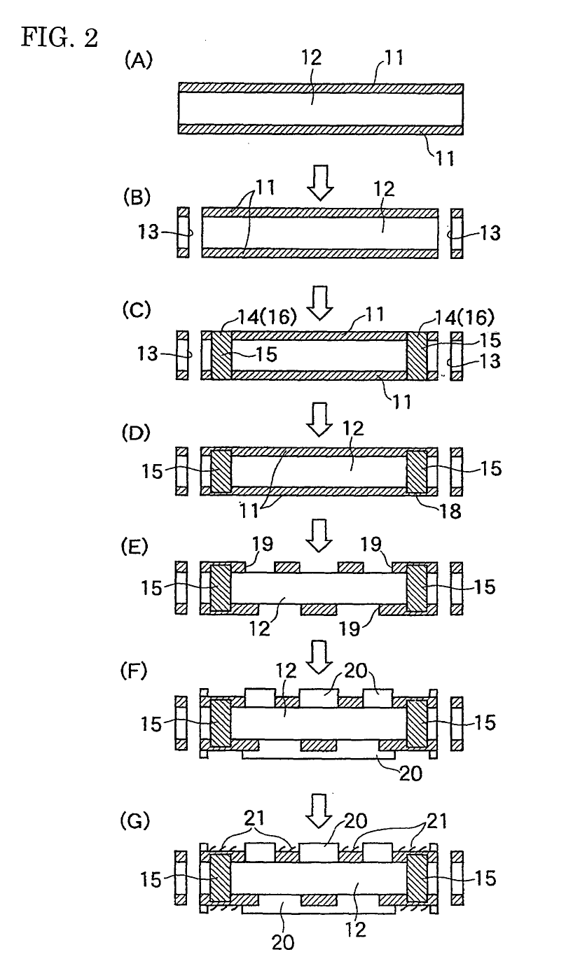

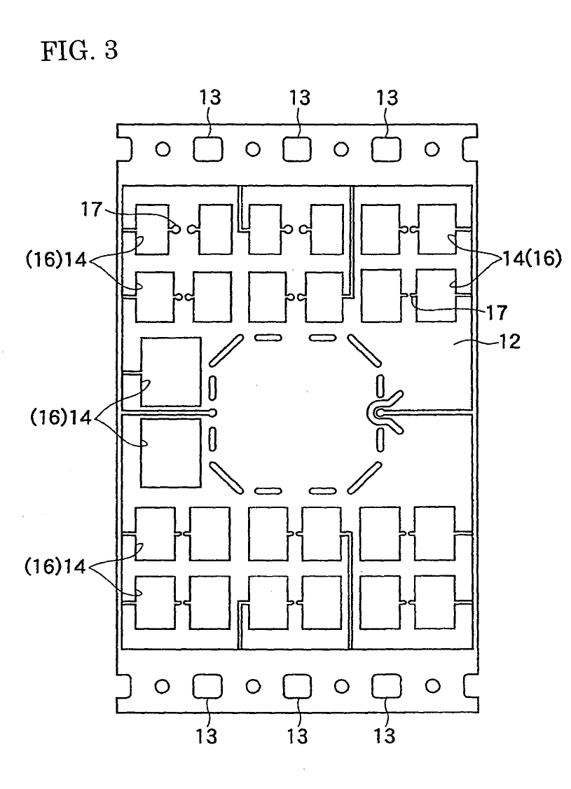

Sprocket holes 13 are perforated (FIG. 2B), by punching, through specified positions, corresponding to sprocket holes 13 of FIG. 2, of a polyimide film 12 having laminated copper layer 11 on both of top and bottom surfaces (FIG. 2A). After through-holes 14 are perforated, by punching, through specified positions, corresponding to through-holes 14 of FIG. 3, of the polyimide film 12, highly heat-resistant implant material strips such as oxygen free copper are superposed on the top and bottom surfaces of the polyimide film 12 followed by the punching to fill the through-holes with the implant material 15 to make via-holes 16 and to simultaneously form land sections 17 (FIG. 2C). In this situation, the surfaces of the polyimide film 12 and the via-holes 16 are matched.

Then, a copper plated layer 18 is formed on the matched surface (FIG. 2D). After the copper plated layer 18 is smoothened and photoresist is applied on the top surface thereof followed by exposure and development for making a mask, the etching is conducted by using the mask to form trenches 19 on the top surface of the polyimide film 12. Further, trenches 19 are similarly formed on the bottom surface of the polyimide film 12 (FIG. 2E). At this stage, the trenches can be formed relatively freely because the copper plated layer has been already covered.

Solder resist 20 is formed such that the trenches 19 of the top and bottom surfaces of the polyimide film are filled and the solder resist is projected from the surfaces (FIG. 2F), and a finished plated layer 21 is formed on the surface other than the solder resist 20 to provide a print circuit board (FIG. 2G).

The print circuit board fabricated in this manner has the reduced probability of generating deficiencies under the conditions of the repeated heating and cooling between higher temperatures and lower temperatures because the via-holes are made of the highly heat-resistant implant material 15.

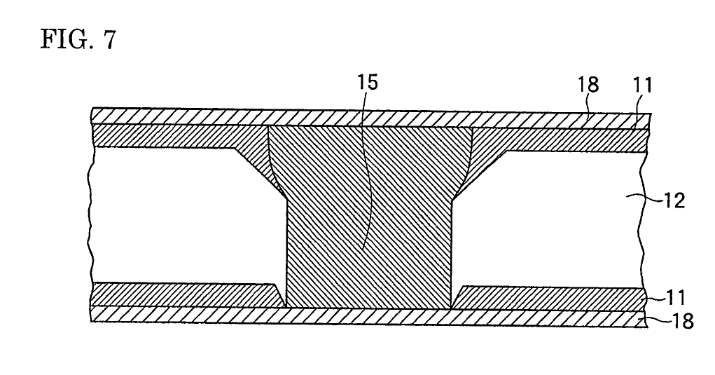

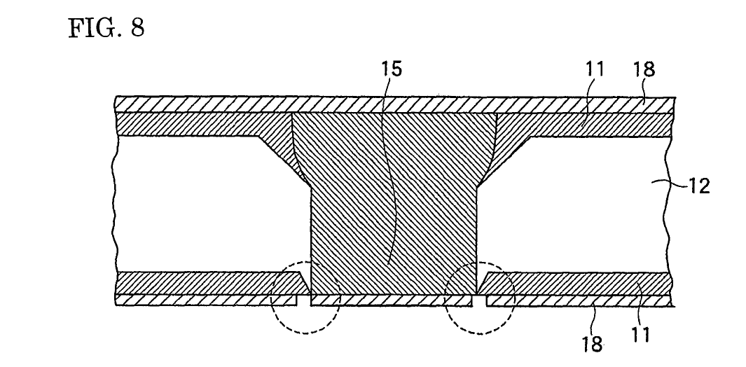

Further, the satisfactory conductivity is secured for a longer period of time because the copper plated layer 18 ensures the reliability of the electric connection with the via-holes 16. While the relatively thicker copper plated layer 18 seldom generates cracks under the conditions of the repeated heating and cooling between higher temperatures and lower temperatures as shown in FIG. 7, the relatively thinner copper plated layer 18 may generates cracks 22 under the conditions of the repeated heating and cooling between higher temperatures and lower temperatures as shown in FIG. 8. However, accordingly, the copper plated layer 18 is desirably formed in a relatively thicker, for example, in a thickness of 1 μm or more, the cracks which give harmful effects on the performance of the print circuit board seldom take place, and no problem arises under the normal operation.

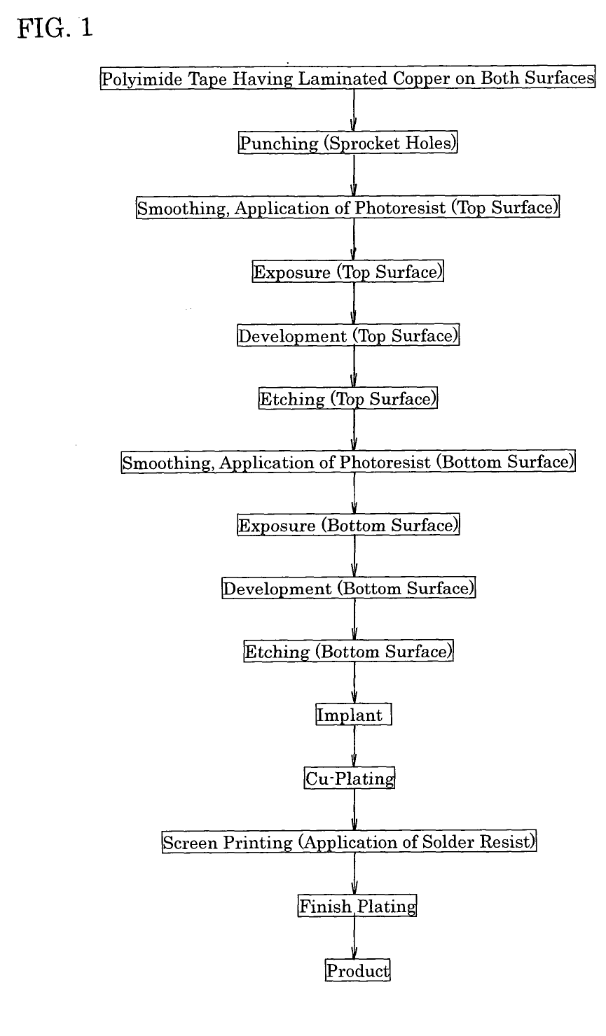

The process of forming the via-holes before making the circuit patterns is described in the present embodiment, though the fabrication process of the print circuit board of the present invention is not restricted to the process of the above mentioned. The conventional fabrication shown in FIG. 1 is also used.

Although Examples of the fabrication of the print circuit board will be described in accordance with the present invention, the present invention shall not be deemed to be restricted thereto.

### EXAMPLE 1

A polyimide film with a width of 35 mm (thickness of polyimide layer was 50 μm; the thicknesses of the laminated copper on the top and bottom surfaces were 12 μm; and tradename name of Nippon Steel Corporation was “Espanex”) having laminated copper on both of the surfaces was used as a tape.

Sprocket holes were perforated through the tape by using a punching-press machine. Then, through-holes having a diameter of about 100 μm were perforated by using the punching-press machine.

The annealed oxygen free copper strip having a thickness about 120 mm were superposed on the top and bottom surfaces of the tape, and the annealed oxygen free copper was implanted into the through-holes by the repunching-press. After the removal of the surplus implanted material by etching, the surface of the tape was copper-plated by using a copper sulfate plating bath under current density of 10A/dm² to form a copper plated layer having a thickness of about 6 μm.

Then, interconnect patterns were formed by etching the top and bottom surfaces in accordance with an ordinary method to provide a print circuit board. In this stage, the fine pitch patterns could be formed and the copper plated layer could be wired relatively freely.

The resistance of the via-holes between the top and bottom surfaces of the print circuit board should be below 3mΩ/hole to provide sufficient conductivity for the 2-metal TAB or the like.

A hot oil test was conducted by dipping the circuit board in the hot oil heated to 260° C. for five seconds and immediately thereafter dipped in the oil at 23° C. for 20 seconds. And it was repeated 100 times. After the test, the connection reliability between the interconnect viaholes made by implant process was sufficient and no cracks were observed on the copper plated layer.

### EXAMPLE 2

A print circuit board was fabricated under the same conditions as are shown on of Example 1 except that the thickness of the copper plated layer was 1 μm.

The resistance of the via-holes between the top and bottom surfaces of the obtained print circuit board was measured to be below 3 mΩ/hole.

The hot oil test was conducted under the same conditions as those of Example 1. After the test, the connection reliability between the interconnect patterns on the top and bottom surfaces of the circuit board was maintained. However, cracks were observed on the copper plated layer.

### EXAMPLE 3

A print circuit board was fabricated under the same conditions as those of Example 1 except that phosphorus-deoxidized copper was used in place of the oxygen free copper as the implant material.

The resistance of the via-holes between the top and bottom surfaces of the obtained print circuit board was measured to be below 3 mΩ/hole.

The hot oil test was conducted under the same conditions as those of Example 1. The connection reliability between the interconnect patterns on the top and bottom surfaces of the circuit board was maintained, and no cracks were observed on the copper plated layer.

### EXAMPLE 4

A print circuit board was fabricated under the same conditions as those of Example 1 except that tough pitch copper was used in place of the oxygen free copper as the implant material.

The resistance of the via-holes between the top and bottom surfaces of the obtained print circuit board was measured to be below 3 mΩ/hole.

The hot oil test was conducted under the same conditions as those of Example 1. The connection reliability between the interconnect patterns on the top and bottom surfaces of the circuit board was maintained, and no cracks were observed on the copper plated layer.

### EXAMPLE 5

A polyimide film with a width of 35 mm (thickness of polyimide layer was 50 μm; the thicknesses of the laminated copper on the top and bottom surfaces were 18 μm; and tradename name of Nippon Steel Corporation was “Espanex”) having laminated cooper on the top and bottom surfaces was used as a tape.

Then, interconnect patterns were formed by etching on the top and bottom surfaces of the tape in accordance with an ordinary method. In this stage, the interconnect patterns were on the top and bottom surfaces are not electrically connected with each other.

Sprocket holes and through-holes were perforated through the tape similarly to Example 1.

After films made of annealed oxygen free copper having a thickness about 0.12 mm were superposed on the top and bottom surfaces of the tape, the annealed oxygen free copper was embedded in the through-holes by the re-punching-press. After the removal of the surplus oxygen free copper film, the surface of the tape was copper-plated by using a copper sulfate plating bath under current density of 10A/dm² to form a print circuit board having a copper plated layer with a thickness of about 6 μm.

The resistance of the via-holes between the top and bottom surfaces of the print circuit board thus obtained was measured to be below 3 mΩ/hole which provided sufficient conductivity for the 2-metal TAB or the like.

The hot oil test was conducted under the same conditions as those of Example 1. The connection reliability between the interconnect patterns on the top and bottom surfaces of the circuit board was maintained, and no cracks were observed on the copper plated layer.

### Comparative Example 1

A print circuit board was fabricated under the same conditions as those of Example 5 except that the diameter of the through-holes was about 100 μm, and the through-holes were filled with a tin-silver alloy material film having a thickness of 0.10 mm in place of the annealed oxygen free copper.

The resistance of the via-holes between the top and bottom surfaces of the print circuit board thus obtained was measured to be below 10 mΩ/hole. This resistance was larger than the resistances of the print circuit boards of the Examples. However, the conductivity in the range used for the 2-metal TAB or the like could be obtained.

The hot oil test was conducted under the same conditions as those of Example 5. The cracks were generated in the via-holes, and the via-holes did not have the sufficient heat-resistance.

1. A print circuit board comprising a dielectric substrate having via-holes perforated therethrough, an implant material filled in the via-holes and selected from a group consisting of oxygen free copper, phosphorus-deoxidized copper and tough pitch copper, and interconnect patterns formed on both surfaces of the substrate and electrically connected to the implant material.

2. The print circuit board as defined in claim 1, wherein the oxygen free copper, the phosphorus-deoxidized copper or the tough pitch copper is annealed oxygen free copper, annealed phosphorus-deoxidized copper or annealed tough pitch copper.

3. The print circuit board as defined in claim 1 further comprising a plated layer in contact with the implant material filled in the via-holes.

4. The print circuit board as defined in claim 3, wherein the plated layer is a copper plated layer having thickness of 1 μm or more.

5. A multi-layered print circuit board comprising a plurality of stacked unit print circuit boards each including a dielectric substrate having via-holes perforated therethrough, an implant material filled in the via-holes and selected from a group consisting of oxygen free copper, phosphorus-deoxidized copper and tough pitch copper, and interconnect patterns formed on both surfaces of the substrate and electrically connected to the implant material.

6. A process of fabricating a print circuit board comprising the steps of:
perforating through-holes through a dielectric substrate,
filling the through-holes with an implant material to form via-holes,
forming a pair of plated layers on both of top and bottom surfaces of the dielectric substrate including both surface ends of the filled implant material, and
forming interconnect patterns on the plated layers.

7. The process of fabricating the print circuit board as defined in claim 6, wherein the implant material is selected from a group consisting of oxygen free copper, phosphorus-deoxidized copper and tough pitch copper.
